(19) United States
(12) Patent Application Publication
(10) Pub. No.: US 2026/0262254 A1
(43) Pub. Date: Sep. 3, 2026

(54) THIN FILM TRANSISTOR AND METHOD FOR MANUFACTURING THIN FILM TRANSISTOR

(71) Applicants: HPSP Co., Ltd., Hwaseong-si, Gyeonggi-do (KR); POSTECH Research and Business Development Foundation, Pohang-si, Gyeongsangbuk-do (KR)

(72) Inventor: Hyunsang HWANG, Daegu (KR)

(21) Appl. No.: 18/879,581

(22) PCT Filed: Jun. 30, 2023
(86) PCT No.: PCT/KR2023/009274

§ 371 Date: Dec. 27, 2024

(30) Foreign Application Priority Data
Jun. 30, 2022 (KR) 10-2022-0080120
Jul. 25, 2022 (KR) 10-2022-0092012

(51) Int. Cl. H10D 30/67; H10D 30/01; H10P 95/90

(52) U.S. Cl. CPC H10D 30/6713; H10D 30/0314; H10D 30/6731; H10P 95/90; H10D 30/6755

(57) ABSTRACT

The present invention relates to a thin film transistor and a method for manufacturing a thin film transistor. The method for manufacturing a thin film transistor, according to an embodiment, may comprise the steps of: forming a diffusion passage layer on a substrate; forming one or more trenches in the diffusion pathway layer; forming a diffusion barrier layer within the trenches; forming an active layer on the diffusion passage layer and the diffusion barrier layer; forming a source and a drain on the active layer; forming a gate insulating layer between the source and the drain; forming a gate on the gate insulating layer; and performing heat treatment.

### FIELD

The present disclosure relates to a thin film transistor and a method for manufacturing a thin film transistor, and more specifically, to an oxide thin film transistor and a method for manufacturing an oxide thin film transistor.

### DESCRIPTION OF RELATED ART

A thin film transistor (TFT) is a type of field effect transistor (FET) manufactured by stacking a semiconductor thin film on an insulating substrate. The TFT includes three electrodes (e.g., a source, a drain, and a gate) and a thin film-shaped active layer (or a channel layer) disposed between the two electrodes. When voltage is applied to the gate electrode, holes gather between the source electrode and the drain electrode, forming a channel, causing current to flow from the source electrode to the drain electrode. The TFT is used in a display device such as an LCD or an OLED.

Examples of a material that constitutes the active layer of the TFT may include amorphous silicon (a-Si), low-temperature polycrystalline silicon (LTPS), and oxide. The TFT whose active layer comprises the oxide is referred to as an oxide TFT. An example of the oxide used in the oxide TFT may be indium-gallium-zinc-oxide (In—Ga—Zn—O, IGZO). Recently, various technologies have been studied to improve electrical characteristics of the oxide TFT and to enhance performance and reliability of the oxide TFT.

Related prior art includes Korean Patent Application Publication No. 10-2016-0131339 and Korean Patent Application Publication No. 10-2022-004795.

### DISCLOSURE

### Technical Purpose

The present disclosure is to provide a thin film transistor and a method for manufacturing a thin film transistor having improved electrical characteristics, performance, and reliability compared to existing ones.

The purpose of the present disclosure is not limited to the above-mentioned purpose, and other purposes and advantages of the present disclosure, which are not mentioned, will be more clearly understood based on embodiments of the present disclosure as described below. In addition, the purposes and advantages of the present disclosure may be realized based on components and combinations thereof described in the Claims.

### Technical Solution

A thin film transistor according to an embodiment may include a substrate, a diffusion pathway layer disposed on the substrate, an active layer disposed on the diffusion pathway layer, a source and a drain disposed on the active layer, a gate insulating layer disposed between the source and the drain, a gate disposed on the gate insulating layer, and a diffusion blocking region formed at locations corresponding to the source and the drain in the diffusion pathway layer.

A method for manufacturing a thin film transistor according to an embodiment may include forming a diffusion pathway layer on a substrate, defining at least one trench in the diffusion pathway layer, forming a diffusion blocking region inside the trench, forming an active layer on the diffusion pathway layer and the diffusion blocking region, forming a source and a drain on the active layer, forming a gate insulating layer between the source and the drain, forming a gate on the gate insulating layer, and performing heat treatment.

### Technical Effect

According to the embodiments, the reliability of the thin film transistor is improved by reducing the oxygen vacancies that cause the defects in the active layer, by restrictively supplying additional oxygen to the active layer via the diffusion blocking region and the diffusion pathway layer during the thin film transistor manufacturing process.

According to the embodiments, because the diffusion blocking region with the different density distributions for the respective areas thereof is formed during the thin film transistor manufacturing process, permeability of a reactant included in the reaction gas may be selectively adjusted.

According to the embodiments, the charge mobility may be stably improved by lowering the thermal budget without causing the thermal damage by forming the passivation layer at the active layer during the thin film transistor manufacturing process.

According to the embodiments, because the charge traps present in the passivation layer of the active layer are passivated by hydrogen during the thin film transistor manufacturing process, the charge mobility may be improved as a charge density of the passivation layer is lowered.

According to the embodiments, because the high-pressure heat treatment process is performed under the low-temperature environment during the thin film transistor manufacturing process, a product yield may be improved by preventing deterioration of a portion vulnerable to heat.

### BRIEF DESCRIPTION OF THE DRAWINGS

FIG. 1 illustrates a structure of a thin film transistor according to a first embodiment.

FIG. 2 illustrates a movement path of ions in reactant gas by heat treatment during a manufacturing process of the thin film transistor according to the first embodiment.

FIG. 3 illustrates a structure of a thin film transistor according to a second embodiment.

FIG. 4 is an enlarged view of A illustrated in FIG. 3.

FIG. 5 illustrates a movement path of ions in reactant gas by heat treatment during a manufacturing process of a thin film transistor according to a second embodiment.

FIG. 6 illustrates a structure of a thin film transistor according to a third embodiment.

FIG. 7 is an enlarged view of B illustrated in FIG. 6.

FIG. 8 illustrates a movement path of ions in reactant gas by heat treatment during a manufacturing process of a thin film transistor according to a third embodiment.

FIGS. 9 to 15 illustrate a manufacturing process of a thin film transistor according to a third embodiment.

FIG. 16 is a flowchart illustrating a method for manufacturing a thin film transistor according to an embodiment.

FIG. 17 is a graph showing driving currents (Iₒₙ) and off-currents (I_{off}) of a thin film transistor manufactured according to a first embodiment and a thin film transistor for which heat treatment is excluded during a manufacturing process.

### DETAILED DESCRIPTIONS

Hereinafter, a preferred embodiment of the present disclosure will be described in detail with reference to the attached drawings. However, the technical idea of the present disclosure may not be limited to the embodiments described herein and may be embodied in other forms. Rather, the embodiments introduced herein are provided such that the disclosed contents may be thorough and complete and such that the idea of the present disclosure may be sufficiently conveyed to those skilled in the art.

In the present disclosure, when it is mentioned that a first component is “on” a second component, it means that the first component is disposed directly on the second component or is disposed indirectly on the second component with a third component being disposed between the first and second components. Further, in the drawings, shapes and sizes may be exaggerated for the effective description of technical contents.

Further, although the terms “first”, “second”, “third”, and the like have been used in the various embodiments of the present disclosure to describe various components, these components should not be limited by these terms. These terms are only used to distinguish one component from another. Thus, what is referred to as a first component in an embodiment may be referred to as a second component in another embodiment. Each embodiment described and illustrated herein also includes a complementary embodiment thereof. Further, “and/or” has been used in the present disclosure with a meaning of including at least one of the preceding and succeeding listed components.

As used herein, the singular constitutes “a” and “an” are intended to include the plural constitutes as well, unless the context clearly indicates otherwise. Furthermore, terms such as “comprise”, “comprising”, “include”, and “including” should not be construed as precluding the presence or addition of one or more other features, integers, operations, elements, components, and/or portions thereof, but rather as specifying the presence of features, integers, operations, elements, and/or components thereof described herein. Furthermore, in the present disclosure, “connect” is used to mean both indirectly and directly connecting a plurality of components to each other.

In addition, in describing the present disclosure below, when it is determined that a specific description of a related known function or component may unnecessarily obscure the gist of the present disclosure, the detailed description will be omitted.

Hereinafter, for convenience of description, a first direction refers to an X-axis of an orthogonal coordinate system, and a second direction refers to a Z-axis of the orthogonal coordinate system. In this regard, the first direction is orthogonal to the second direction.

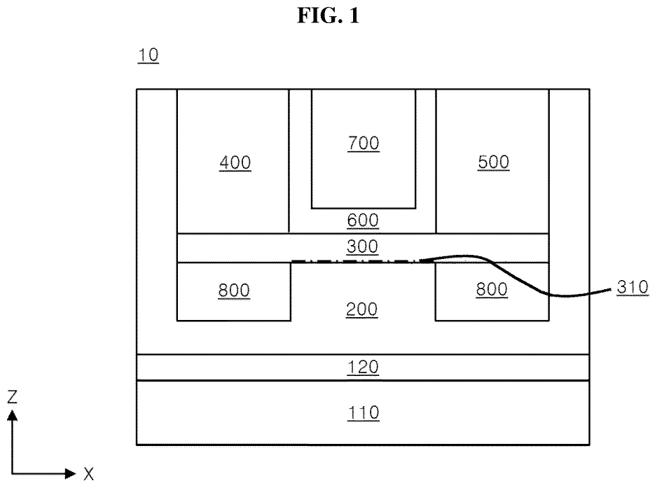

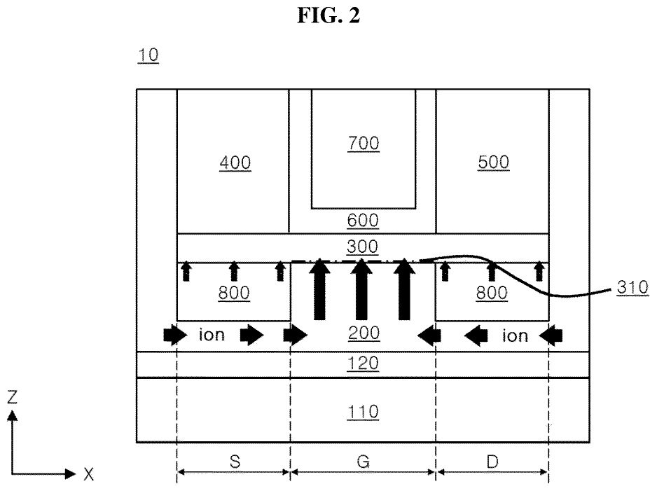

FIG. 1 illustrates a structure of a thin film transistor according to a first embodiment. In addition, FIG. 2 illustrates a movement path of ions in reactant gas by heat treatment during a manufacturing process of the thin film transistor according to the first embodiment.

A thin film transistor 10 according to the first embodiment may include substrates 110 and 120, a diffusion pathway layer 200, a metal oxide active layer 300, a source 400, a drain 500, a gate insulating layer 600, a gate 700, and a diffusion blocking region 800.

The substrates 110 and 120 may include a base substrate layer 110 and a buffer substrate layer 120.

The base substrate layer 110 may be a single crystal substrate. A single crystal semiconductor layer may be formed on at least one surface of the base substrate layer 110. The single crystal semiconductor layer may be made of one of Si, Ge, SiGe, GeSn, InSb, GaAs (a III-V group semiconductor), GaP, InAlAs, InGaAs, GaSbP, GaAsSb, and InP, but the constituent materials of the single crystal semiconductor layer are not limited thereto.

The buffer substrate layer 120 may have a lattice constant different from that of the base substrate layer 110 to minimize lattice stress. In another embodiment, the lattice constant and/or a crystal structure of the buffer substrate layer 120 may be the same as or similar to the lattice constant and/or a crystal structure of the base substrate layer 110.

The buffer substrate layer 120 may be a crystalline substance formed via epitaxial growth on the base substrate layer 110. The buffer substrate layer 120 may be formed by doping the base substrate layer 110 with impurities of a material different from that of the base substrate layer 110. In an embodiment, the buffer substrate layer 120 may be relatively heavily doped compared to the base substrate layer 110 as it extends to a higher layer.

The buffer substrate layer 120 may have different lattice constants for respective layers. For example, the lattice constant of the buffer substrate layer 120 may gradually increase as it goes from a lower layer to a higher layer.

The diffusion pathway layer 200 may be disposed on the substrates 110 and 120. The diffusion pathway layer 200 may also be referred to as a diffusion layer.

The diffusion pathway layer 200 may serve as a passage for ionized reactant gas provided during heat treatment of the active layer 300. That is, when the heat treatment is performed, ions generated from the reactant gas may pass through the diffusion pathway layer 200. The ionized reactant gas according to an embodiment may include at least one of oxygen ions, hydrogen ions, fluorine ions, and nitrogen ions, but a type of the ionized reactant gas may not be limited thereto.

The diffusion pathway layer 200 may be made of oxide such as SiO₂, but a type of the material constituting the diffusion pathway layer 200 may not be limited thereto.

The diffusion pathway layer 200 may be disposed between the substrates 110 and 120 and the active layer 300. The diffusion pathway layer 200 may pass the ionized reactant gas supplied from the outside therethrough.

The diffusion pathway layer 200 may be the oxide. In addition, the diffusion pathway layer 200 may have a low dielectric properties. In an embodiment, the diffusion pathway layer 200 may be SiO₂, but the type of the diffusion pathway layer 200 may not be limited thereto.

In an embodiment, the diffusion pathway layer 200 may have a thickness in a range of 20 nm to 50 nm.

In an embodiment, oxygen (O₂) or ozone (O₃) may be provided as the reactant gas during the heat treatment. In this case, the diffusion pathway layer 200 may act as a tunnel through which oxygen ions pass.

In an embodiment, hydrogen (H₂) or deuterium (D₂) may be provided as the reactant gas during the heat treatment. In this case, the diffusion pathway layer 200 may serve as a tunnel through which hydrogen ions pass.

In another embodiment, gas containing fluorine (Fₓ) or nitrogen (Nₓ) may be provided as the reactant gas during the heat treatment. In this case, the diffusion pathway layer 200 may serve as a tunnel through which fluorine ions or nitrogen ions pass.

The active layer 300 may be disposed to be in direct contact with the source 400 and the drain 500. The active layer 300 may be electrically connected to each of the source 400 and the drain 500.

The active layer 300 may be a channel area, which is a passage through which carriers such as holes or electrons move. Therefore, the active layer 300 may also be referred to as a channel layer.

When voltage is applied to the gate 700, to prevent the carriers of the active layer 300 from penetrating the gate insulating layer 600 and entering the gate 700, the active layer 300 may be made of a thin film having a high dielectric constant.

In an embodiment, the active layer 300 may be made of an oxide semiconductor material based on zinc oxide (ZnO).

In an embodiment, the active layer 300 may further include at least In, Ga, Sn, or Al in addition to Zn. For example, the active layer 300 may include at least one of indium-gallium-zinc-oxide (In—Ga—Zn—O, IGZO), indium-tin-zinc-oxide (In—Sn—Zn—O, ISZO), indium-aluminum-zinc-oxide (In—Al—Zn—O, IAZO), tin-aluminum-zinc-oxide (Sn—Al—Zn—O, SAZO), and tin-zinc-oxide (Sn—Zn—O, SZO).

In an embodiment, the active layer 300 may have a thickness in a range of 8 nm to 12 nm. Preferably, the active layer 300 may have a thickness of 10 nm.

In an embodiment, the active layer 300 may be formed via a vacuum deposition process or a solution process. For example, the active layer 300 may be formed via a deposition process such as physical vapor deposition (PVD) like sputtering, atomic layer deposition (ALD), and metal organic chemical vapor deposition (MOCVD), or a solution process such as a sol-gel method or a colloidal particle method.

A passivation layer 310 may be formed at one side of the active layer 300.

As illustrated in FIG. 2, when the diffusion blocking region 800 is formed in a partial area of the diffusion pathway layer 200, a tunnel through which the ions included in the reactant gas may pass may be formed in the diffusion pathway layer 200. For example, an area of the diffusion pathway layer 200 between two patterns of the diffusion blocking region 800 in FIG. 2 may be defined as the tunnel. In the state in which the tunnel for the movement of the ions is formed in the diffusion pathway layer 200, the passivation layer 310 may be formed by performing the heat treatment in a reactant gas atmosphere.

In one embodiment, the reactant gas may include at least one component among oxygen, hydrogen, fluorine, and nitrogen.

In one embodiment, the passivation layer 310 may be formed by heat treatment performed in a high-pressure oxygen atmosphere. In another embodiment, the passivation layer 310 may be formed by heat treatment under a high-pressure hydrogen atmosphere. In another embodiment, the passivation layer 310 may be formed by performing a primary heat treatment in the high-pressure oxygen atmosphere and then performing a secondary heat treatment in the high-pressure hydrogen atmosphere.

When the heat treatment is performed in the oxygen atmosphere, oxygen vacancies, i.e., defects, present in the active layer 300 are reduced.

In an embodiment, when the heat treatment is performed in the oxygen atmosphere, a pressure of oxygen may be in a range of 2 atm to 50 atm. In another embodiment, when the heat treatment is performed in the oxygen atmosphere, a pressure of oxygen may be in a range of 5 atm to 20 atm.

In an embodiment, the heat treatment performed in the oxygen atmosphere may be performed in a temperature range of 100° C. to 600° C. In another embodiment, the heat treatment performed in the oxygen atmosphere may be performed in a temperature range of 200°C. to 400° C.

When the heat treatment is performed in the hydrogen atmosphere, oxygen vacancies or charge traps present in the active layer 300 and/or the passivation layer 310 may be passivated by hydrogen ions. Accordingly, a charge density of the oxide TFT 10 is reduced and a charge mobility thereof is improved.

In an embodiment, when the heat treatment is performed in the hydrogen atmosphere, a pressure of hydrogen may be in a range of 2 atm to 50 atm. In another embodiment, when the heat treatment is performed in the hydrogen atmosphere, a pressure of hydrogen may be in a range of 5 atm to 20 atm.

In an embodiment, the heat treatment performed in the hydrogen atmosphere may be performed in a temperature range of 100° C. to 600° C. In another embodiment, the heat treatment performed in the hydrogen atmosphere may be performed in a temperature range of 200°C. to 400° C.

When the passivation layer 310 is formed, the oxygen vacancies of the active layer 300 may be reduced. When the oxygen vacancies are reduced, the charge mobility increases, so that a threshold voltage (Vth) of the oxide TFT 10 may be lowered.

The passivation layer 310 may be locally formed in one area of the active layer 300. The formation area of the passivation layer 310 may be determined by an arrangement relationship between the diffusion pathway layer 200 and the diffusion blocking region 800. For example, a location or an area size of the passivation layer 310 may vary depending on a ratio of the diffusion blocking region 800 in the diffusion pathway layer 200 or a location, a cross-sectional area, or a volume of the diffusion blocking region 800.

The active layer 300 may be divided into a source area S, a gate area G, and a drain area D. The source area S is an area that is in contact with the source 400, the gate area G is an area that is in contact with the gate insulating layer 600, and the drain area D is an area that is in contact with the drain 500.

Crystal structures of the active layer 300 in the source area S, the drain area D, and the gate area G may be different from each other. A combination of materials constituting the gate area G may be relatively more stable than that of materials constituting the source area S or the drain area D. In addition, the closer the source area S or the drain area D is to the gate area G, the more relatively stable the combination of materials constituting the source area S or the drain area D may be.

When the active layer 300 is formed according to a method for manufacturing the thin film transistor 10 in an embodiment, an on/off ratio (Iₒₙ/I_{off}) of the thin film transistor 10 may be higher than in the past.

Each of the source 400 and the drain 500 may be formed on the active layer 300. Each of the source 400 and the drain 500 may be in direct contact with the active layer 300.

The source 400 and the drain 500 may be arranged to be spaced apart from each other. The source 400 and the drain 500 may be arranged to face each other in the first direction. The source 400 may serve as a source electrode. The drain 500 may serve as a drain electrode.

The source 400 and the drain 500 may electrically connect respective ends of the active layer 300 to each other. Depending on the embodiment, locations or roles of the source 400 and the drain 500 may be switched.

The gate insulating layer 600 may be disposed between the source 400 and the drain 500. The gate insulating layer 600 may insulate the gate 700 from the active layer 300, the source 400, and the drain 500. The gate insulating layer 600 may prevent parasitic coupling of the substrates 110 and 120 by the gate 700. The gate insulating layer 600 may prevent an undesirable conductive channel from being formed in the substrates 110 and 120 when the thin film transistor 10 is conductive.

In an embodiment, the gate insulating layer 600 may be made of Al₂O₃, but a type of material constituting the gate insulating layer 600 may not be limited thereto.

The gate insulating layer 600 may be formed via a deposition process. In an embodiment, the gate insulating layer 600 may have a thickness in a range of 10 nm to 20 nm, preferably 15 nm.

The gate 700 may be disposed within the gate insulating layer 600. The gate 700 may serve as a gate electrode that controls a flow of current passing through the active layer 300. In the gate area G, the gate 700 may face the active layer 300.

The gate 700 may be insulated from the source 400, the drain 500, and the active layer 300 by the gate insulating layer 600.

The gate 700 may be disposed between the source 400 and the drain 500. In an embodiment, the gate 700 may be made of a metal material. For example, the gate 700 may include at least one material of TiN and W.

The gate 700 may be formed via a deposition process. A length of the gate 700 may be determined by the thickness of the gate insulating layer 600 and lengths of the source 400 and the drain 500.

The diffusion blocking region 800 may face the source 400 and the drain 500 in the second direction. The diffusion blocking region 800 may be disposed beneath the active layer 300. The patterns of the diffusion blocking region 800 may be arranged to correspond to the source area S and the drain area D, respectively.

The diffusion blocking region 800 may be made of a material having a denser structure and a higher hardness than the material of the diffusion pathway layer 200. For example, the diffusion blocking region 800 may be made of silicon nitride (SiₓN_{y}). In this regard, 1≤x≤3 and 1≤y≤4. For example, the diffusion blocking region 800 may be made of Si₃N₄. When the diffusion blocking region 800 is made of Si₃N₄ having a dense structure and a high hardness, the ions generated from the reactant gas may not pass through the diffusion blocking region 800. As the patterns of the diffusion blocking region 800 are disposed at the locations respectively corresponding to the source area S and the drain area D, the ions generated from the reactant gas may be prevented from being injected into the source 400 and the drain 500.

Accordingly, the ions (e.g., oxygen, hydrogen, fluorine, or nitrogen ions) generated from the reactant gas during the heat treatment may not pass through the diffusion blocking region 800. Depending on the embodiment, some of the ions (e.g., the oxygen, hydrogen, fluorine, or nitrogen ions) included in the reactant gas may pass through the diffusion blocking region 800.

In an embodiment, when the heat treatment is performed with the reactant gas, an amount of ions directly injected into the active layer 300 through the tunnel formed in the diffusion pathway layer 200 may be greater than an amount of ions injected into the active layer 300 through the diffusion blocking region 800.

That is, when the heat treatment is performed with the reactant gas, the movement path of the ions included in the reactant gas, the amount of ions injected into the active layer 300, or the injection location of the ions may be adjusted by the diffusion blocking region 800.

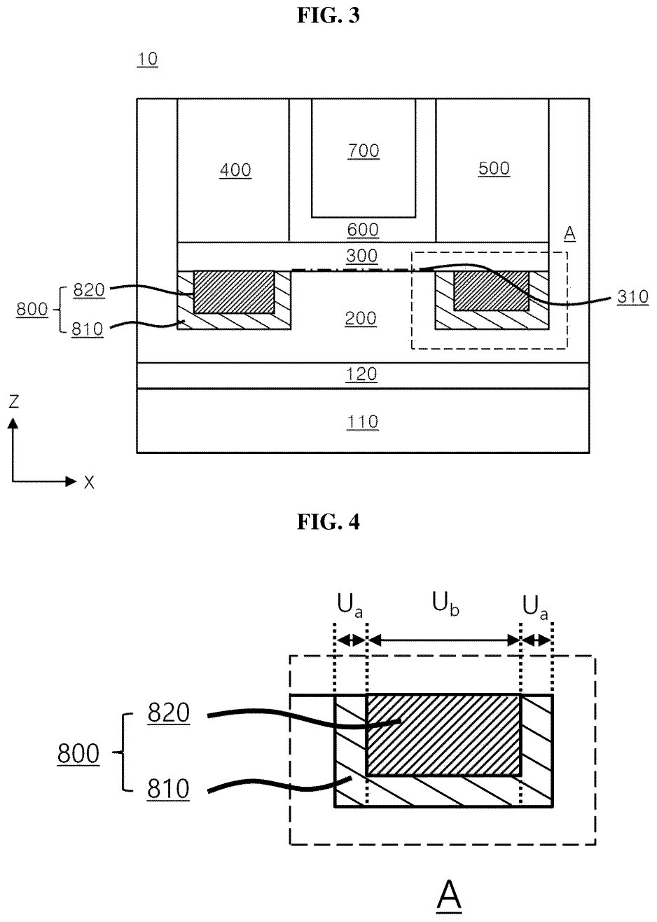

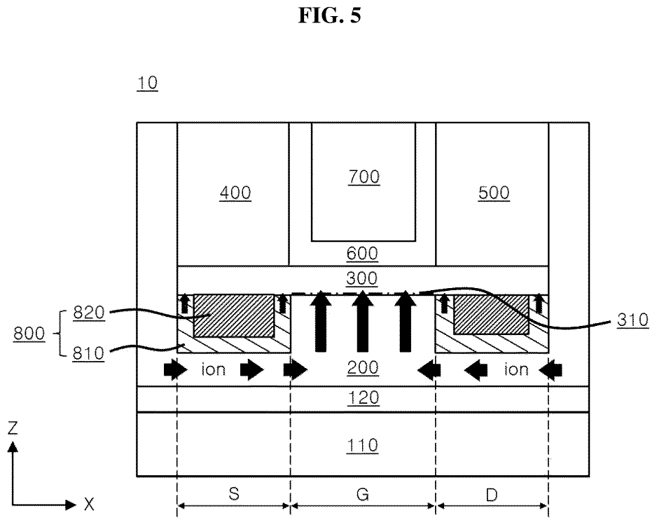

FIG. 3 illustrates a structure of a thin film transistor according to a second embodiment. FIG. 4 is an enlarged view of A illustrated in FIG. 3. FIG. 5 illustrates a movement path of ions in reactant gas by heat treatment during a manufacturing process of a thin film transistor according to a second embodiment.

A thin film transistor 10 according to the second embodiment may include substrates 110 and 120, a diffusion pathway layer 200, a metal oxide active layer 300, a source 400, a drain 500, a gate insulating layer 600, a gate 700, and a diffusion blocking region 800. A structure of the thin film transistor 10 according to the second embodiment is the same as the structure of the thin film transistor 10 according to the first embodiment except for the diffusion blocking region 800. Therefore, descriptions of other components except for the diffusion blocking region 800 are omitted below.

The diffusion blocking region 800 may face the source 400 and the drain 500 in the second direction. The diffusion blocking region 800 may be disposed beneath the active layer 300. Patterns of the diffusion blocking region 800 may be arranged to correspond to a source area S and a drain area D, respectively.

The diffusion blocking region 800 may be made of a material having a denser structure and a higher hardness than the material of the diffusion pathway layer 200. Accordingly, ions (e.g., oxygen, hydrogen, fluorine, or nitrogen ions) included in reactant gas may not pass through the diffusion blocking region 800 during heat treatment. Depending on the embodiment, some of the ions (e.g., the oxygen, hydrogen, fluorine, or nitrogen ions) included in the reactant gas may pass through the diffusion blocking region 800.

In the first embodiment described above, the diffusion blocking region 800 comprises a single layer. However, in other embodiments, the diffusion blocking region 800 may be composed of a plurality of layers. For example, as illustrated in FIGS. 3 to 5, the diffusion blocking region 800 according to the second embodiment may include a first diffusion blocking region 810 and a second diffusion blocking region 820.

The first diffusion blocking region 810 and the second diffusion blocking region 820 may be made of different materials. Depending on the embodiment, the first diffusion blocking region 810 and the second diffusion blocking region 820 may be made of the same type of material with different densities.

An ion permeability of the first diffusion blocking region 810 and an ion permeability of the second diffusion blocking region 820 may be different from each other. In an embodiment, the ion permeability of the second diffusion blocking region 820 may be relatively lower than the ion permeability of the first diffusion blocking region 810.

In addition, a density of the first diffusion blocking region 810 and a density of the second diffusion blocking region 820 may be different from each other. In an embodiment, the density of the second diffusion blocking region 820 may be relatively higher than the density of the first diffusion blocking region 810.

In an embodiment, the second diffusion blocking region 820 may have a structure relatively denser than that of the first diffusion blocking region 810. In an embodiment, a hardness of the second diffusion blocking region 820 may be relatively higher than a hardness of the first diffusion blocking region 810.

In an embodiment, the first diffusion blocking region 810 may be made of a first material. The first material may be silicon oxynitride (SiₓO_{y}N_{z}). In this regard, 1≤x≤3, 1≤y≤2, and 1≤z≤3. For example, the first diffusion blocking region 810 may be made of SiON or Si₂ON₂.

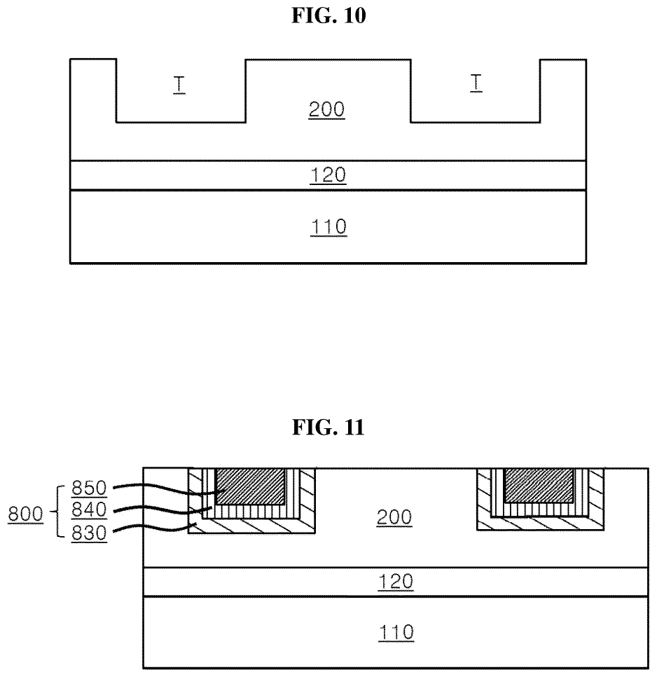

The first diffusion blocking region 810 may be formed to surround an inner wall of a trench T (see FIG. 10). The first diffusion blocking region 810 may be formed via a deposition process such as physical vapor deposition (PVD) like sputtering, atomic layer deposition (ALD), and metal organic chemical vapor deposition (MOCVD), or a solution process such as a sol-gel method or a colloidal particle method. The first diffusion blocking region 810 may also be formed via low pressure chemical vapor deposition (LPCVD).

In an embodiment, the second diffusion blocking region 820 may be made of a second material. The second material may be silicon nitride (SiₓN_{y}). In this regard, 1≤x≤3 and 1≤y≤4. For example, the second diffusion blocking region 820 may be made of Si₃N₄.

The second diffusion blocking region 820 may be formed to fill a trench-shaped space defined inside the first diffusion blocking region 810. The second diffusion blocking region 820 may be formed via a deposition process such as physical vapor deposition (PVD) like sputtering, atomic layer deposition (ALD), and metal organic chemical vapor deposition (MOCVD), or a solution process such as a sol-gel method or a colloidal particle method. The second diffusion blocking region 820 may also be formed via low pressure chemical vapor deposition (LPCVD).

Referring to FIG. 4, the diffusion blocking region 800 may be divided into two areas Uₐ and U_{b} in the first direction. The first area Uₐ is an area corresponding to the first diffusion blocking region 810, and the second area U_{b} is an area corresponding to the second diffusion blocking region 820 and the first diffusion blocking region 810.

An ion permeability of the first area Uₐ and an ion permeability of the second area U_{b} may be different from each other. A density of the first area Uₐ and a density of the second area U_{b} may be different from each other.

In an embodiment, the diffusion blocking region 800 may have different density distributions for the respective areas Uₐ and U_{b}. For example, in FIG. 4, the first area Uₐ may be made of a single material, but two different materials may constitute different level of regions in the second area U_{b}. More specifically, in the second area U_{b}, the first diffusion blocking region 810 and the second diffusion blocking region 820 made of the material having the higher density than that of the first diffusion blocking region 810 may constitute the layers. In this case, the ion permeability of the first area Uₐ may be higher than the ion permeability of the second area U_{b}.

Depending on the embodiment, the ions may pass through the first area Uₐ, but may not pass through the second area U_{b}.

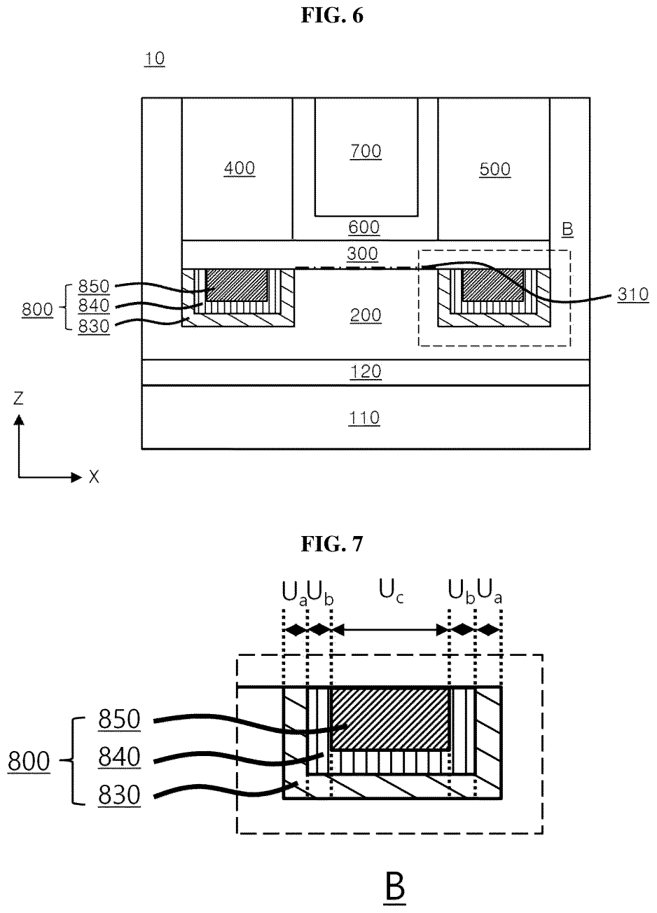

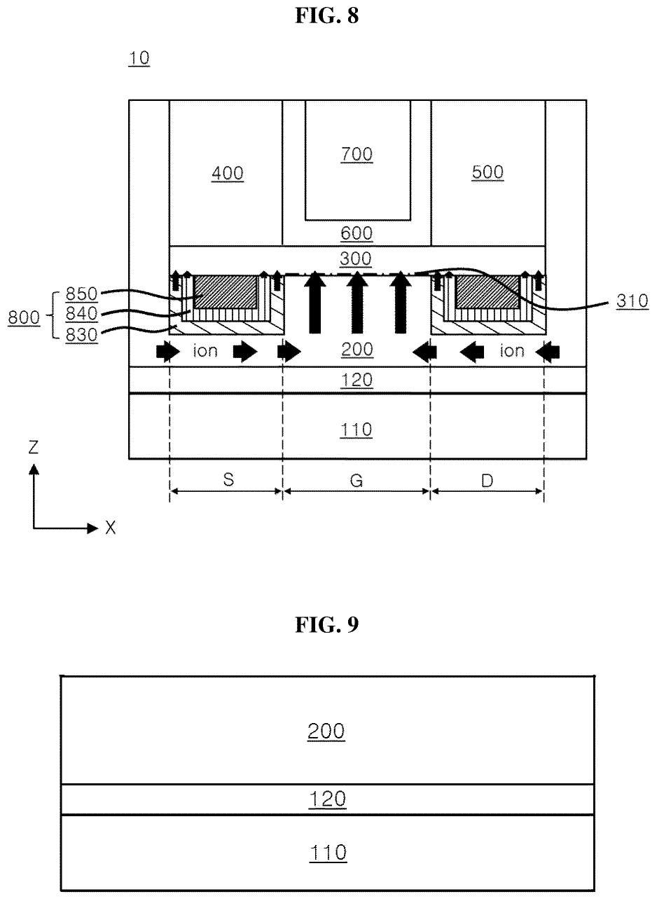

FIG. 6 illustrates a structure of a thin film transistor according to a third embodiment. FIG. 7 is an enlarged view of B illustrated in FIG. 6. FIG. 8 illustrates a movement path of ions in reactant gas by heat treatment during a manufacturing process of a thin film transistor according to a third embodiment.

A thin film transistor 10 according to the third embodiment may include substrates 110 and 120, a diffusion pathway layer 200, a metal oxide active layer 300, a source 400, a drain 500, a gate insulating layer 600, a gate 700, and a diffusion blocking region 800. A structure of the thin film transistor 10 according to the third embodiment is the same as the structure of the thin film transistor 10 according to the first embodiment or the second embodiment except for the diffusion blocking region 800. Therefore, descriptions of other components except for the diffusion blocking region 800 are omitted below.

The diffusion blocking region 800 may face the source 400 and the drain 500 in the second direction. The diffusion blocking region 800 may be disposed beneath the active layer 300. Patterns of the diffusion blocking region 800 may be arranged to correspond to a source area S and a drain area D, respectively.

The diffusion blocking region 800 may be made of a material having a denser structure and a higher hardness than a material of the diffusion pathway layer 200. Accordingly, ions (e.g., oxygen, hydrogen, fluorine, or nitrogen ions) included in reactant gas during heat treatment may not pass through the diffusion blocking region 800. Depending on the embodiment, some of the ions (e.g., the oxygen, hydrogen, fluorine, or nitrogen ions) included in the reactant gas may pass through the diffusion blocking region 800.

In the first embodiment described above, the diffusion blocking region 800 comprises the single layer. However, in other embodiments, the diffusion blocking region 800 may be composed of the plurality of layers. For example, as illustrated in FIGS. 6 to 8, the diffusion blocking region 800 according to the third embodiment may include a first diffusion blocking region 830, a second diffusion blocking region 840, and a third diffusion blocking region 850. Depending on the embodiment, the diffusion blocking region 800 may be composed of four or more layers.

The first diffusion blocking region 830, the second diffusion blocking region 840, and the third diffusion blocking region 850 may be made of different materials. Depending on the embodiment, the first diffusion blocking region 830, the second diffusion blocking region 840, and the third diffusion blocking region 850 may be made of the same type of material with different densities.

An ion permeability of the first diffusion blocking region 830, an ion permeability of the second diffusion blocking region 840, and an ion permeability of the third diffusion blocking region 850 may be different from each other. For example, the ion permeability of the third diffusion blocking region 850 may be relatively lower than the ion permeability of the first diffusion blocking region 830 and the ion permeability of the second diffusion blocking region 840, and the ion permeability of the second diffusion blocking region 820 may be relatively lower than the ion permeability of the first diffusion blocking region 810.

In addition, a density of the first diffusion blocking region 830, a density of the second diffusion blocking region 840, and a density of the third diffusion blocking region 850 may be different from each other. For example, the density of the third diffusion blocking region 850 may be relatively higher than the density of the first diffusion blocking region 830 and the density of the second diffusion blocking region 840, and the density of the second diffusion blocking region 840 may be relatively higher than the density of the first diffusion blocking region 830.

In an embodiment, the third diffusion blocking region 850 may have a structure relatively denser than those of the first diffusion blocking region 830 and the second diffusion blocking region 840, and the second diffusion blocking region 840 may have the structure relatively denser than that of the first diffusion blocking region 830.

In an embodiment, a hardness of the third diffusion blocking region 850 may be relatively higher than a hardness of the first diffusion blocking region 830 and a hardness of the second diffusion blocking region 840, and the hardness of the second diffusion blocking region 840 may be relatively higher than the hardness of the first diffusion blocking region 830.

In an embodiment, the first diffusion blocking region 830 may be made of a first material. The first material may be silicon oxynitride (SiₓO_{y}N_{z}). In this regard, 1≤x≤3, 1≤y≤2, and 1≤z≤3. For example, the first diffusion blocking region 810 may be made of SiON or Si₂ON₂.

The first diffusion blocking region 830 may be formed to surround an inner wall of a trench T (see FIG. 10). The first diffusion blocking region 830 may be formed via a deposition process such as physical vapor deposition (PVD) like sputtering, atomic layer deposition (ALD), and metal organic chemical vapor deposition (MOCVD), or a solution process such as a sol-gel method or a colloidal particle method. The first diffusion blocking region 830 may also be formed via low pressure chemical vapor deposition (LPCVD).

In an embodiment, the second diffusion blocking region 840 may be made of a second material. The second material may be silicon nitride (SiₓN_{y}). In this regard, 1≤x≤3 and 1≤y≤4. For example, the second diffusion blocking region 840 may be made of Si₃N₄.

The second diffusion blocking region 840 may be formed to surround an inner wall of the first diffusion blocking region 830 having a trench shape. The second diffusion blocking region 840 may be formed via a deposition process such as physical vapor deposition (PVD) like sputtering, atomic layer deposition (ALD), and metal organic chemical vapor deposition (MOCVD), or a solution process such as a sol-gel method or a colloidal particle method. The second diffusion blocking region 840 may also be formed via low pressure chemical vapor deposition (LPCVD).

In an embodiment, the third diffusion blocking region 850 may be made of a third material. The third material may be silicon nitride (SiₓN_{y}). In this regard, 1≤x≤2 and 1≤y≤2. For example, the third diffusion blocking region 850 may be made of SiN or Si₂N.

The third diffusion blocking region 850 may be formed to fill a trench-shaped space defined inside the second diffusion blocking region 840. The third diffusion blocking region 850 may be formed via a deposition process such as physical vapor deposition (PVD) like sputtering, atomic layer deposition (ALD), and metal organic chemical vapor deposition (MOCVD), or a solution process such as a sol-gel method or a colloidal particle method. The third diffusion blocking region 850 may also be formed via low pressure chemical vapor deposition (LPCVD).

Referring to FIG. 7, the diffusion blocking region 800 may be divided into three areas Uₐ, U_{b}, and U_{c} in the first direction. The first area Uₐ is an area corresponding to the first diffusion blocking region 830, the second area U_{b} is an area corresponding to the second diffusion blocking region 840 and the first diffusion blocking region 830, and the third area U_{c} is an area corresponding to the third diffusion blocking region 850, the second diffusion blocking region 840, and the first diffusion blocking region 830.

An ion permeability of the first area Uₐ, an ion permeability of the second area U_{b}, and an ion permeability of the third area U_{c} may be different from each other. A density of the first area Uₐ, a density of the second area U_{b}, and a density of the third area U_{c} may be different from each other.

In an embodiment, the diffusion blocking region 800 may have different density distributions for the respective areas Uₐ, U_{b}, and U_{c}. For example, in FIG. 4, the first area Uₐ may be made of the single material, but two different materials may constitute different level of regions in the second area U_{b}, and three different materials may constitute different level of regions in the third area U_{c}. More specifically, the first diffusion blocking region 830 and the second diffusion blocking region 840 made of the material having the higher density than that of the first diffusion blocking region 830 may constitute the layers in the second area U_{b}, and the first diffusion blocking region 830, the second diffusion blocking region 840 made of the material having the higher density than that of the first diffusion blocking region 830, and the third diffusion blocking region 850 made of the material having the higher density than that of the second diffusion blocking region 840 may constitute the layers in the third area U_{c}. In this case, the ion permeability of the first area Uₐ may be greater than the ion permeability of the second area U_{b} and the ion permeability of the third area U_{c}, and the ion permeability of the second area U_{b} may be greater than the ion permeability of the third area U_{c}.

Depending on the embodiment, the ions may pass through the first area Uₐ, but may not pass through the second area U_{b} or the third area U_{c}. In other embodiments, the ions may pass through the first area Uₐ and the second area U_{b}, but may not pass through the third area U_{c}.

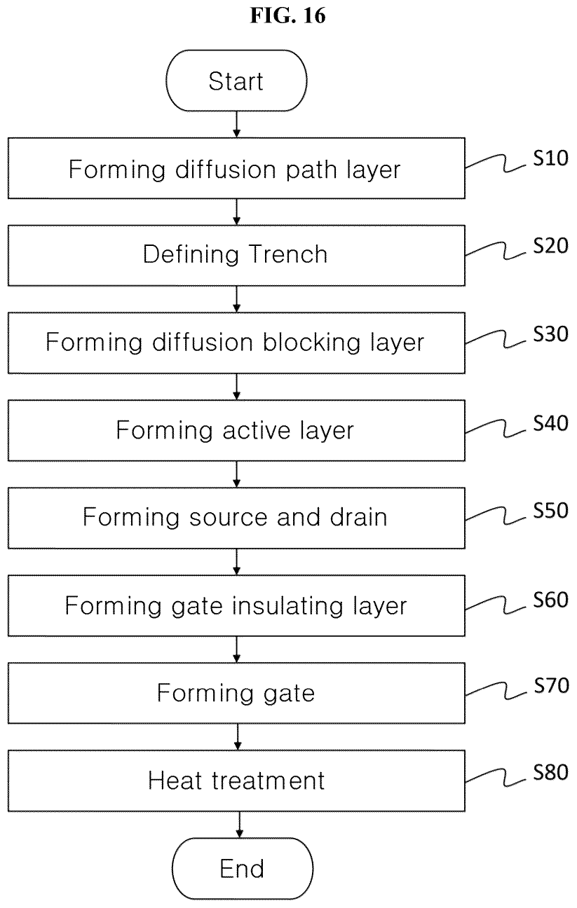

FIGS. 9 to 15 illustrate a manufacturing process of a thin film transistor according to a third embodiment. FIG. 16 is a flowchart illustrating a method for manufacturing a thin film transistor according to an embodiment.

First, referring to FIGS. 9 and 16, the diffusion pathway layer 200 is formed on the substrates 110 and 120 (S10). For example, the diffusion pathway layer 200 may be made of oxide such as SiO₂ and may be formed via deposition.

Next, referring to FIGS. 10 and 16, one or more trenches T are defined by selectively removing an arbitrary area of the diffusion pathway layer 200 (S20). For example, the trench T may be defined via selective etching.

Next, referring to FIGS. 11 and 16, the diffusion blocking region 800 is formed inside the trench T defined in the diffusion pathway layer 200 (S30). FIG. 11 illustrates the diffusion blocking region 800 including the first diffusion blocking region 830, the second diffusion blocking region 840, and the third diffusion blocking region 850 according to the third embodiment. In this case, the first diffusion blocking region 830, the second diffusion blocking region 840, and the third diffusion blocking region 850 may be sequentially formed inside the trench T.

When the diffusion blocking region 800 according to the second embodiment is formed in the diffusion blocking region forming step (S30), the first diffusion blocking region 810 and the second diffusion blocking region 820 may be sequentially formed inside the trench T. When the diffusion blocking region 800 according to the first embodiment is formed in the diffusion blocking region forming step (S30), the diffusion blocking region 800 may be formed by filling a single material inside the trench T.

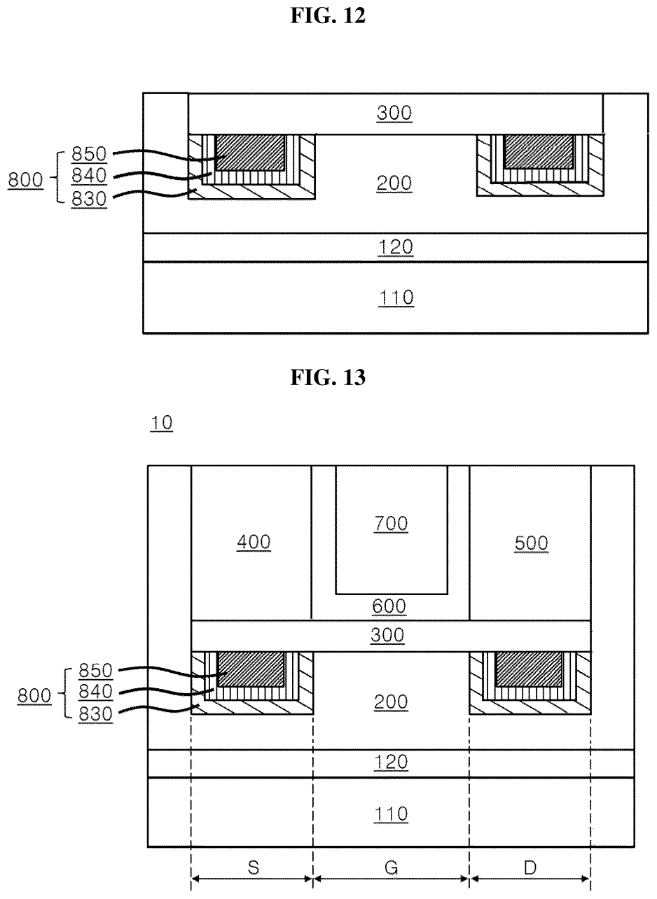

Next, referring to FIGS. 12 and 16, the active layer 300 is formed on the diffusion pathway layer 200 and the diffusion blocking region 800 (S40). For example, the active layer 300 may be formed via a vacuum deposition process or a solution process.

Next, referring to FIGS. 13 and 16, the source 400 may be formed in the source area S on the active layer 300, and the drain 500 may be formed in the drain area D on the active layer 300 (S50). A formation order of the source 400 and the drain 500 may vary depending on the embodiment. A material (e.g., SiO₂) identical to that of the diffusion pathway layer 200 may be disposed at one side of each of the source 400 and the drain 500.

In addition, the gate insulating layer 600 is formed in the gate area G on the active layer 300 (S60). The gate insulating layer 600 may be formed between the source 400 and the drain 500. The source 400 and the drain 500 may be arranged parallel to the gate insulating layer 600 in the first direction.

In addition, the gate 700 is formed inside the gate insulating layer 600 (S70).

The source and drain forming step (S50), the gate insulating layer forming step (S60), and the gate forming step (S70) may be interchanged.

Next, referring to FIG. 16, heat treatment for the thin film transistor 10 may be performed (S80).

In an embodiment, the heat treatment step (S80) may include a first heat treatment step performed in an oxygen atmosphere and a second heat treatment step performed in a hydrogen atmosphere.

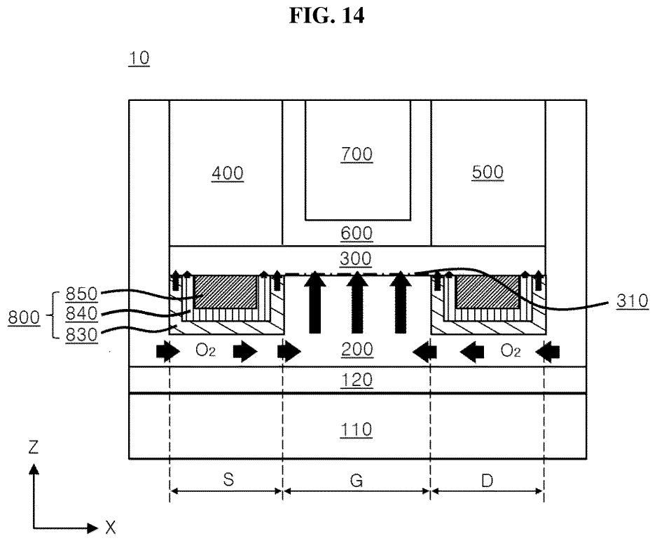

For example, as illustrated in FIG. 14, the first heat treatment step for the thin film transistor 10 may be first performed in an atmosphere of reactant gas (e.g., oxygen (O₂) or ozone (O₃)) including oxygen. When the first heat treatment is performed, oxygen ions generated from the reactant gas may be injected into the thin film transistor 10 via the diffusion pathway layer 200.

The first heat treatment step may be performed in an atmosphere of oxygen (O₂) or ozone (O₃) at a concentration of 100%. However, a concentration of the reactant gas including oxygen may vary depending on the embodiment. For example, the first heat treatment step may be performed using reactant gas having a concentration equal to or higher than 50% or a concentration of 100%.

The first heat treatment step may be performed in a pressure range of 2 to 50 atm, preferably in a pressure range of 5 to 20 atm. The first heat treatment step may be performed under one of wet, dry, or supercritical conditions or environments. The first heat treatment step may be performed in a temperature range of 100° C. to 600°C., preferably in a temperature range of 200°C. to 400° C.

When the first heat treatment is performed, the oxygen ions may pass through a tunnel formed in the diffusion pathway layer 200 and be injected into the active layer 300. However, a relatively small amount of oxygen ions may pass through the diffusion blocking region 800. Depending on the embodiment, the oxygen ions may not pass through the diffusion blocking region 800. Therefore, a relatively great amount of oxygen ions may be injected into a portion of the active layer 300 corresponding to the gate area G, and a relatively small amount of oxygen ions may be injected into a portion of the active layer 300 corresponding to the source area S or the drain area D.

Accordingly, a relatively great amount of oxygen vacancies may be reduced in the portion of the active layer 300 corresponding to the gate area G compared to the portion of the active layer 300 corresponding to the source area S or the drain area D.

In one example, when the diffusion blocking region 800 comprises the plurality of layers and divided into the multiple areas, as in the second or third embodiment, the oxygen ion permeability may be different for each area. For example, when the diffusion blocking region 800 is divided into the first area Uₐ, the second area U_{b}, and the third area U_{c}, as in the third embodiment, the oxygen ion permeability may decrease in an order of the first area Uₐ, the second area U_{b}, and the third area U_{c}. Accordingly, a reduction amount of oxygen vacancies may decrease from the first area Uₐ to the third area U_{c}.

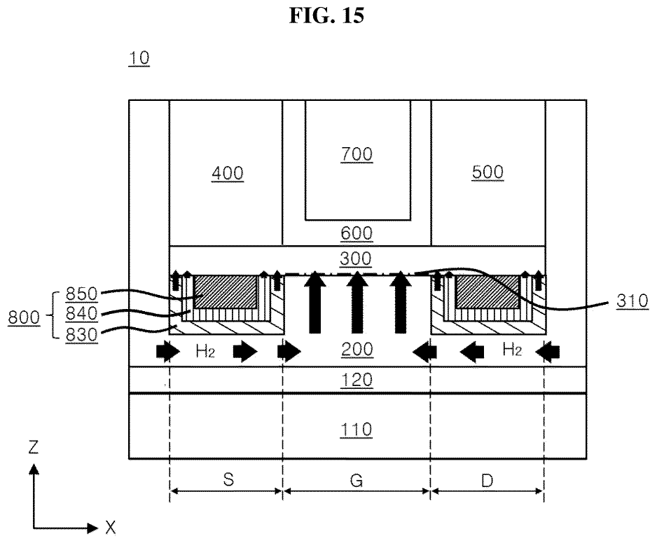

After the first heat treatment is performed, the second heat treatment may be performed. For example, as illustrated in FIG. 15, the second heat treatment step for the thin film transistor 10 may be performed in an atmosphere of reactant gas (e.g., hydrogen (H₂) or deuterium (D₂)) including hydrogen. When the second heat treatment is performed, hydrogen ions generated from the reactant gas may be injected into the thin film transistor 10 via the diffusion pathway layer 200.

The second heat treatment step may be performed in an atmosphere of hydrogen (H₂) or deuterium (D₂) having a concentration in a range of 3% to 10%, preferably 4%. However, a concentration of the reactant gas including hydrogen may vary depending on the embodiment. For example, the second heat treatment step may be performed using reactant gas having a concentration equal to or higher than 50% or a concentration of 100%.

The second heat treatment step may be performed in a pressure range of 2 to 50 atm, preferably in a pressure range of 5 to 20 atm. The second heat treatment step may be performed under one of wet, dry, or supercritical conditions or environments. The second heat treatment step may be performed in a temperature range of 100° C. to 600° C., preferably in a temperature range of 200°C. to 400° C.

When the second heat treatment is performed, the hydrogen ions may pass through a tunnel formed in the diffusion pathway layer 200 and be injected into the active layer 300. However, a relatively small amount of hydrogen ions may pass through the diffusion blocking region 800. Depending on the embodiment, the hydrogen ions may not pass through the diffusion blocking region 800. Therefore, a relatively great amount of hydrogen ions may be injected into a portion of the active layer 300 corresponding to the gate area G, and a relatively small amount of hydrogen ions may be injected into a portion of the active layer 300 corresponding to the source area S or the drain area D.

In one example, when the diffusion blocking region 800 comprises the plurality of layers and divided into the multiple areas, as in the second or third embodiment, the hydrogen ion permeability may be different for each area. For example, when the diffusion blocking region 800 is divided into the first area Uₐ, the second area U_{b}, and the third area U_{c}, as in the third embodiment, the hydrogen ion permeability may decrease in an order of the first area Uₐ, the second area U_{b}, and the third area U_{c}.

The passivation layer 310 is formed at the portion of the active layer 300 corresponding to the gate area G by the second heat treatment. Accordingly, the oxygen vacancies or the charge traps present in the active layer 300 and/or the passivation layer 310 may be passivated by the hydrogen ions. Accordingly, the charge density of the oxide TFT 10 is reduced and the charge mobility is improved.

Depending on the embodiment, only one of the first heat treatment step and the second heat treatment step described above may be selectively performed in the heat treatment step (S80).

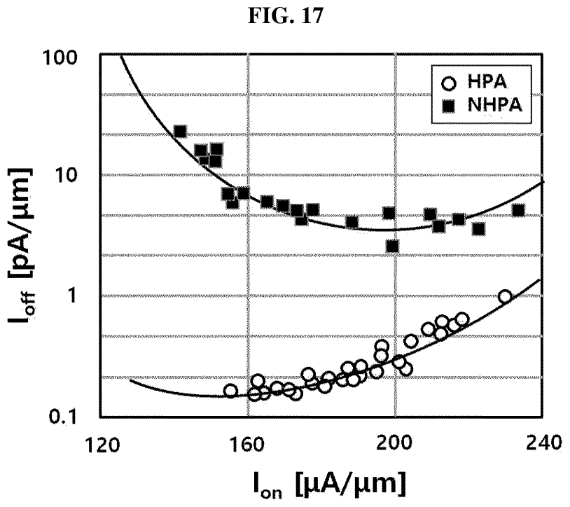

FIG. 17 is a graph showing driving currents (Iₒₙ) and off-currents (I_{off}) of a thin film transistor manufactured according to a first embodiment and a thin film transistor for which heat treatment is excluded during a manufacturing process.

In FIG. 17, HPA is data representing the driving current (Iₒₙ) and the off-current (I_{off}) of the thin film transistor manufactured according to the first embodiment described above, and NHPA is data representing the driving current (Iₒₙ) and the off-current (I_{off}) of the thin film transistor for which the heat treatment step (S80) described above is not performed during the manufacturing process.

As illustrated in FIG. 17, when the heat treatment step (S80) is performed according to the first embodiment described above during the manufacturing process of the thin film transistor, the on/off ratio (Iₒₙ/I_{off}) of the thin film transistor is higher than when the heat treatment step (S80) is not performed.

In addition, as illustrated in FIG. 17, when the heat treatment step (S80) is not performed during the manufacturing process of the thin film transistor, a phenomenon in which the driving current (Iₒₙ) is significantly reduced when the off-current (I_{off}) increases occurs. However, when the heat treatment step (S80) is performed according to the first embodiment described above during the manufacturing process of the thin film transistor, the phenomenon in which the driving current (Iₒₙ) is reduced when the off-current (I_{off}) increases is ameliorated.

Although the embodiments have been described with reference to the accompanying drawings as described above, the present disclosure is not limited to the embodiments disclosed in the present disclosure and the drawings, and various modifications may be made thereto by a person skilled in the art. In addition, although an effect according to a configuration of the present disclosure is not explicitly described in describing the embodiments of the present disclosure above, a predictable effect from the configuration should also be recognized.

What is claimed is:

1. A thin film transistor comprising:
a substrate;
a diffusion pathway layer disposed on the substrate;
an active layer disposed on the diffusion pathway layer;
a source and a drain disposed on the active layer;
a gate insulating layer disposed between the source and the drain;
a gate disposed on the gate insulating layer; and
a diffusion blocking region formed at locations corresponding to the source and the drain in at least partial area of the diffusion pathway layer.

2. The thin film transistor of claim 1, wherein the diffusion blocking region is made of a single material.

3. The thin film transistor of claim 1, wherein the diffusion blocking region comprises a plurality of layers respectively made of different materials having different ion permeabilities.

4. The thin film transistor of claim 1, wherein the diffusion blocking region is divided into a plurality of areas having different level of regions.

5. The thin film transistor of claim 4, wherein ion permeabilities of the respective areas are different from each other.

6. The thin film transistor of claim 1, wherein an ion permeability of the diffusion blocking region and an ion permeability of the diffusion pathway layer are different from each other.

7. The thin film transistor of claim 1, further comprising a passivation layer formed over at least partial area of the active layer.

8. A method for manufacturing a thin film transistor, the method comprising:
forming a diffusion pathway layer on a substrate;
forming at least one trench in the diffusion pathway layer;
forming a diffusion blocking region inside the trench;
forming an active layer on the diffusion pathway layer and the diffusion blocking region;
forming a source and a drain on the active layer;
forming a gate insulating layer between the source and the drain;
forming a gate on the gate insulating layer; and
performing heat treatment.

9. The method of claim 8, wherein the diffusion blocking region is made of a single material.

10. The method of claim 8, wherein the diffusion blocking region comprises a plurality of layers respectively made of different materials having different ion permeabilities.

11. The method of claim 8, wherein the diffusion blocking region is divided into a plurality of areas having different level of regions.

12. The method of claim 11, wherein ion permeabilities of the respective areas are different from each other.

13. The method of claim 8, wherein the performing of the heat treatment includes:
performing first heat treatment in an oxygen atmosphere; and
performing second heat treatment in a hydrogen atmosphere.

14. The method of claim 13, wherein the first heat treatment or the second heat treatment is performed in a pressure range of 2 atm to 50 atm.

15. The method of claim 13, wherein the first heat treatment or the second heat treatment is performed in a temperature range of 100°C. to 600°C.
